(19) United States
(12) Patent Application Publication
(10) Pub. No.: US 2013/0344690 A1
(43) Pub. Date: Dec. 26, 2013

(54) METHOD OF MANUFACTURING SEMICONDUCTOR DEVICE

(71) Applicant: Masahiko KANDA, Saitama-ken (JP)

(72) Inventor: Masahiko KANDA, Saitama-ken (JP)

(73) Assignee: Kabushiki Kaisha Toshiba, Tokyo (JP)

(21) Appl. No.: 13/600,958

(22) Filed: Aug. 31, 2012

(30) Foreign Application Priority Data
Jun. 20, 2012 (JP) 2012-138825

(51) Int. Cl. H01L 21/22

(52) U.S. Cl. CPC H01L 21/22
USPC 438/542

(57) ABSTRACT

According to one embodiment, in a method of manufacturing a semiconductor device, a gate electrode material film is anisotropically etched using a mask having a predetermined pattern so as to form a first gate electrode on a first region, first dummy gates on the space area of the first region, a second gate electrode on a second region and second dummy gates on the space area of the second region. The first dummy gates have a first coverage and are disposed so as to surround the first gate electrode. The second dummy gates have a second coverage and are disposed so as to surround the second gate electrode. A first insulating film is anisotropically etched so as to form a first sidewall having a first thickness on the first gate electrode and a second sidewall having a second thickness larger than the first thickness on the second gate electrode.

### CROSS REFERENCE TO RELATED APPLICATION

This application is based upon and claims the benefit of priority from the prior Japanese Patent Application No. 2012-138825, filed on Jun. 20, 2012, the entire contents of which are incorporated herein by reference.

### FIELD

Embodiments described herein relate generally to a method of manufacturing a semiconductor device.

### BACKGROUND

Conventionally, there is a method of manufacturing a semiconductor device in such a manner that ion implantations to form channels of insulated gate field effect transistors (MOS transistors) are performed individually so that thresholds of the MOS transistors are different each other in a same chip.

The semiconductor device including MOS transistors of which thresholds are different is manufactured as follows, for example.

There are first and second regions of a semiconductor substrate in which first and second MOS transistors are formed respectively. Firstly, a first ion implantation is performed in the first region of the semiconductor substrate in order to form a first channel of the first MOS transistor after masking the second region of the semiconductor substrate. Secondly, a second ion implantation is performed in the second region of the semiconductor substrate in order to form a second channel of the second MOS transistor after masking the first region of the semiconductor substrate.

Otherwise, an ion implantation is performed in the first and the second regions of the semiconductor substrate in order to form the first and the second channels. Thereafter, an additional ion implantation is performed in the first region of the semiconductor substrate after masking the second region of the semiconductor substrate in order to form the first channel completely.

Next, first and second gate electrodes are formed in the first and the second regions of the semiconductor substrate with a gate insulating film interposed in between.

Since at least one process of forming the mask and two processes of implanting are required, there is a problem that the number of processes increases. Since the amount of the impurity fluctuates in accordance with the increase of dose amount, so that there is also a problem that the thresholds of the MOS transistors fluctuate.

### BRIEF DESCRIPTION OF THE DRAWINGS

FIGS. 1A and 1B are views showing a semiconductor device according to an embodiment;

FIGS. 2A to 5C are cross-sectional views showing steps of manufacturing the semiconductor device in sequential order according to the embodiment;

FIG. 6 is cross-sectional view showing the steps of manufacturing the semiconductor device according to the embodiment;

FIG. 7 is a graph showing the threshold characteristics of the semiconductor device according to the embodiment;

FIG. 8 is a flowchart showing the steps of manufacturing the semiconductor device in comparison with steps of manufacturing a semiconductor device of a comparative example according to the embodiment;

FIG. 9 is a view showing the main portion of the semiconductor device according to the embodiment;

FIG. 10 is a view showing the main portion of the semiconductor device according to the embodiment;

FIGS. 11A and 11B are views showing another semiconductor device according to the embodiment;

### DETAILED DESCRIPTION

According to one embodiment, in a method of manufacturing a semiconductor device, a gate electrode material film is formed on first and second regions of a semiconductor substrate having a first conductivity type with a gate insulating film interposed in between. The gate electrode material film is anisotropically etched using a mask having a predetermined pattern so as to form a first gate electrode on the first region, a plurality of first dummy gates on the space area of the first region, a second gate electrode on the second region and a plurality of second dummy gates on the space area of the second region. The first dummy gates have a first coverage respectively and are disposed so as to surround the first gate electrode. The second dummy gates have a second coverage different from the first coverage respectively and are disposed so as to surround the second gate electrode. a first insulating film is formed on the first and the second gate electrodes. The first insulating film is anisotropically etched so as to form a first sidewall on the first gate electrode and a second sidewall on the second gate electrode. The first sidewall has a first thickness. The second sidewall has a second thickness larger than the first thickness. An impurity is implanted into the first and the second regions in a self-align manner so as to form a pair of first impurity diffusion layers and a pair of second impurity diffusion layers. The impurity has a second conductivity type. The first impurity diffusion layers are disposed so as to interpose the first gate electrode therebetween. The second impurity diffusion layers are disposed so as to interpose the second gate electrode therebetween.

Hereinafter, embodiments will be described with reference to the drawings. In the drawings, same reference characters denote the same or similar portions.

### Embodiment

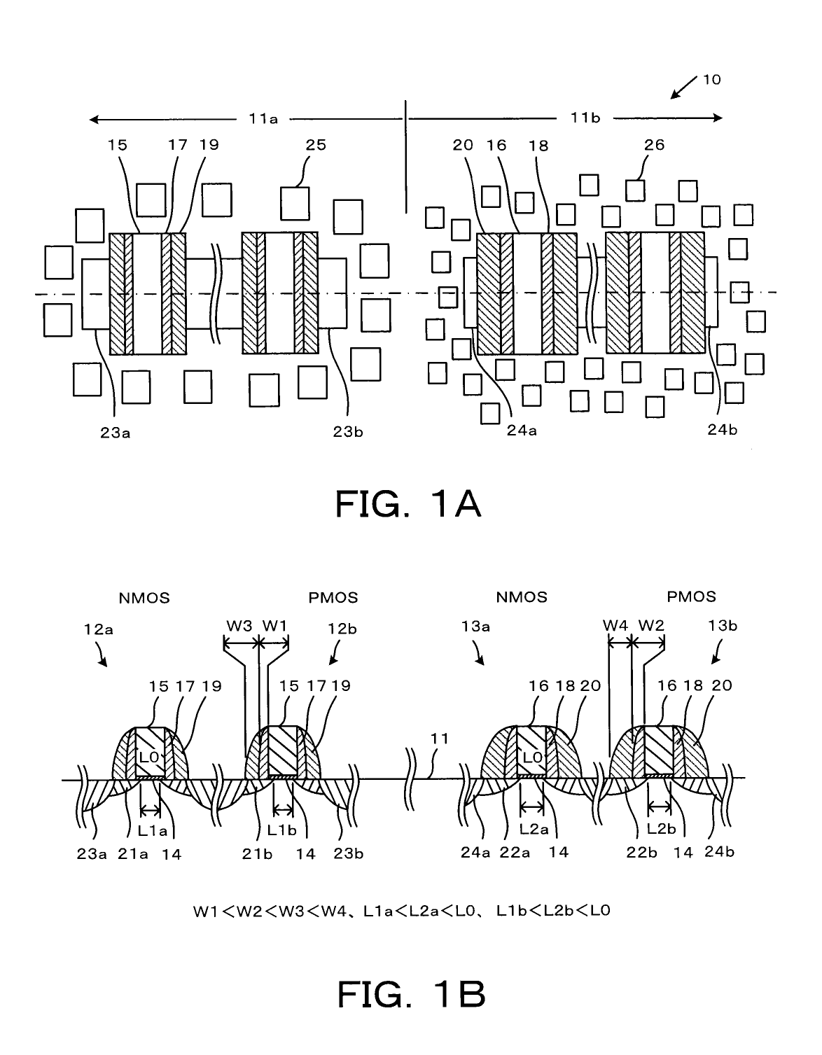

A semiconductor device of an embodiment will be described with reference to FIGS. 1A and 1B. FIG. 1A is a plan view of the semiconductor device. FIG. 1B is a cross-sectional view of the semiconductor device taken along the A-A line and viewed in the direction of the arrows A in FIG. 1A.

As shown in FIGS. 1A and 1B, in the semiconductor device of the embodiment, there are first and second regions 11a, 11b of a semiconductor substrate 11. An N-channel insulated gate field effect transistor (NMOS transistor) 12a and a P-channel insulated gate field effect transistor (PMOS transistor) 12b are provided with the first region 11a. An N-channel insulated gate field effect transistor (NMOS transistor) 13a and a P-channel insulated gate field effect transistor (PMOS transistor) 13b are provided with the second region 11b.

There is a relationship of Vth1a<Vth2a and Vth1b<Vth2b, where Vth1a is the threshold of the NMOS transistor 12a, Vth1b is the threshold of the PMOS transistor 12b, Vth2a is the threshold of the NMOS transistor 13a and Vth2b is the threshold of the PMOS transistor 13b.

The semiconductor substrate 11 is an N-type silicon substrate, for example. The first region 11a and the second region 11b are electrically isolated by an element isolation layer (not shown), for example.

The NMOS transistor 12a and the PMOS transistor 12b are adjacent with the element isolation layer (not shown) interposed in between, and work as a CMOS inverter. Similarly, the NMOS transistor 13a and the PMOS transistor 13b are adjacent with the element isolation layer (not shown) interposed in between, and work as a CMOS inverter, for example.

A well layer (not shown) is provided in the portion of the semiconductor substrate 11 between the element-isolation layers. A Region to form a channel (not shown) is provided in the well layer. In the regions to form the channels of the NMOS transistors 12a, 13a, the impurity concentrations are substantially same. Similarly, in the regions to form the channels of the PMOS transistors 12b, 13b, the impurity concentrations are substantially same.

In the NMOS transistors 12a and PMOS transistor 12b, a first gate electrode 15 is provided on the semiconductor substrate 11 with a gate insulating film 14 interposed in between. In the NMOS transistors 13a, 13a, a second gate electrode 16 is provided on the semiconductor substrate 11 with the gate insulating film 14 interposed in between.

The size of the first gate electrode 15 and the size of the second gate electrode 16 are substantially same. The width of the first gate electrode 15 and the width of the second gate electrode 16 are substantially equal in a direction parallel to the semiconductor substrate 11, and are denoted by L0.

A first sidewall 17 with a first thickness W1 is provided on the first gate electrode 15. A second sidewall 18 with a second thickness W2 larger than the first thickness W1 is provided on the second gate electrode 16 (i.e. W1<W2).

Furthermore, third sidewalls 19 with a third thickness W3 are provided on the first gate electrode 15 with the first sidewalls 17 interposed in between. Fourth sidewalls 20 with a fourth thickness W4 larger than the third thickness W3 are provided on the second gate electrode 16 (W3<W4).

There is a relationship of W1<W2<W3<W4 among the first to the fourth sidewalls 17, 18, 19, 20.

The definition of the thicknesses of the first to fourth sidewalls 17, 18, 19, 20 is not particularly limited. In the specification, the thicknesses of the first to fourth sidewalls 17, 18, 19, 20 are a thickness of the lower portion respectively.

In the NMOS transistor 12a, a pair of first impurity diffusion layers 21a is provided in the semiconductor substrate 11 so that the first gate electrode 15 is interposed in between. The first impurity diffusion layer 21a extends up to the portion below the first gate electrode 15 beyond the first sidewall 17.

Moreover, a pair of third impurity diffusion layers 23a is provided in the semiconductor substrate 11 being in contact with the first impurity diffusion layer 21a so that the first gate electrode 15 is interposed in between. The third impurity diffusion layer 23a extends up to the portion below the third sidewall 19.

In the PMOS transistor 12b, a pair of first impurity diffusion layers 21b is provided in the semiconductor substrate 11 so that the first gate electrode 15 is interposed in between. The first impurity diffusion layer 21b extends up to the portion below the first gate electrode 15 beyond the first sidewall 17.

Moreover, a pair of third impurity diffusion layers 23b is provided in the semiconductor substrate 11 being in contact with the first impurity diffusion layer 21b so that the first gate electrode 15 is interposed in between. The third impurity diffusion layer 23a extends up to the portion below the third sidewall 19.

Similarly, in the NMOS transistor 13a, a pair of second impurity diffusion layers 22a is provided in the semiconductor substrate 11 so that the second gate electrode 16 is interposed in between. The second impurity diffusion layer 22a extends up to the portion below the second gate electrode 16 beyond the second sidewall 18.

Moreover, a pair of fourth impurity diffusion layers 24a is provided in the semiconductor substrate 11 being in contact with the second impurity diffusion layer 22a so that the second gate electrode 16 is interposed in between. The fourth impurity diffusion layer 24a extends up to the portion below the fourth sidewall 20.

In the PMOS transistor 13b, a pair of second impurity diffusion layers 22b is provided in the semiconductor substrate 11 so that the second gate electrode 16 is interposed in between. The second impurity diffusion layer 22b extends up to the portion below the second gate electrode 16 beyond the second sidewall 18.

Moreover, a pair of fourth impurity diffusion layers 24b is provided in the semiconductor substrate 11 being in contact with the second impurity diffusion layer 22b so that the second gate electrode 16 is interposed in between. The fourth impurity diffusion layer 24b extends up to the portion below the fourth sidewall 20.

The amount of the impurity of the first impurity diffusion layer 21a is substantially equal to the amount of the impurity of the second impurity diffusion layer 22a. The amount of the impurity of the third impurity diffusion layer 23a is substantially equal to the impurity of the fourth impurity diffusion layer 24a.

A distance L1a (a first distance) between the pair of first impurity diffusion layers 21a is smaller than L0 (i.e. L1a<L0). The distance L1a corresponds to the channel length of the NMOS transistor 12a and is a factor to determine the threshold Vth1a of the NMOS transistor 12a.

A distance L2a (a second distance) between the pair of second impurity diffusion layers 22a is smaller than L0 and larger than L1a (i.e. L1a<L2a<L0). The distance L2a corresponds to the channel length of the NMOS transistor 13a and is a factor to determine the threshold Vth2a of the NMOS transistor 13a. Therefore, there is a relationship of Vth1a<Vth2a.

The amount of the impurity of the first impurity diffusion layer 21b is substantially equal to the amount of the impurity of the second impurity diffusion layer 22b. The amount of the impurity of the third impurity diffusion layer 23b is substantially equal to the amount of the impurity of the fourth impurity diffusion layer 24b.

A distance L1b (a first distance) between the pair of first impurity diffusion layers 21b is smaller than L0 (i.e. L1b<L0). The distance L1b corresponds to the channel length of the NMOS transistor 12b and is a factor to determine the threshold Vth1b of the NMOS transistor 12b.

A distance L2b (a second distance) between the pair of second impurity diffusion layers 22b is smaller than L0 and larger than L1b (i.e. L1b<L2b<L0). The distance L2b corresponds to the channel length of the PMOS transistor 13b and is a factor to determine the threshold Vth2b of the PMOS transistor 13b. Therefore, there is a relationship of Vth1b<Vth2b.

Multiple first dummy gates 25 having a first coverage are provided in the space area of the first region 11a so as to surround the first gate electrode 15. The first dummy gates 25 are disposed in a dispersive manner.

The first gate dummy 25 is a square. The first coverage is expressed by a relationship of a1²/(a1+c1)², where “a1” is the size of the square and “c1” is the distance from a square adjacent. A total coverage on the first region 11a depends on the product of the first coverage and the number of first dummy gates 25.

Similarly, multiple second dummy gates 26 having a second coverage are provided in the space area of the second region 11b so as to surround the second gate electrode 16. The second dummy gates 26 are disposed in a dispersive manner.

The second gate dummy 26 is a square. The second coverage is expressed by a relationship of 2²/(a2+c2)², where “a2” is the size of the square and “c2” is the distance from a square adjacent. A total coverage on the second region 11b depends on the product of the second coverage and the number of second dummy gates 26.

The total coverage of the second dummy gates 26 is set larger than the total coverage of the first dummy gates 25.

As described later, when an insulating film is conformally formed on the first and the second gate electrodes 15, 16 and is anisotropically etched so as to form the first and the second sidewalls 17, 18, the first and the second dummy gates 25, 26 make the thickness of the first sidewall 17 differ from the thickness of the second sidewall 18 in accordance with each total coverage.

Specifically, in RIE (Reactive Ion Etching) method, a phenomenon (loading effect) that the etching rate decreases as the increase of the total coverage is available.

When a interlayer dielectric film which is formed on the semiconductor substrate 11 so as to bury the first and the second gate electrodes 15, 16 is polished by CMP (Chemical Mechanical Polishing) method so as to expose the uppermost surfaces of the first and the second gate electrodes 15, 16, the first gate dummy 25 and the second gate dummy 26 are used as an auxiliary implement to prevent the first and the second gate electrodes 15, 16 from dishing.

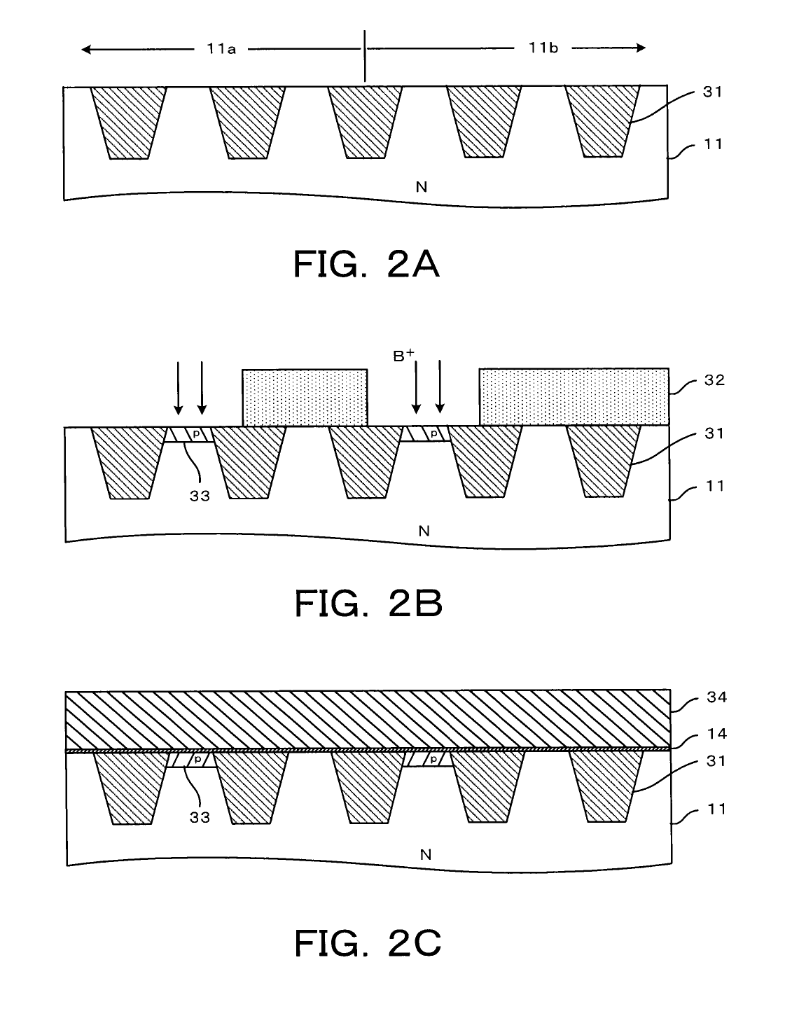

Next, the method of manufacturing the semiconductor device 10 is explained. FIGS. 2A to 6 are cross-sectional views showing steps of manufacturing the semiconductor device 10 in sequential order.

As shown in FIG. 2A, a trench is formed in the semiconductor substrate 11. An insulating film is buried into the trench by CVD (Chemical vapor Deposition) Method, so that an element isolation layer 31 is formed.

As shown in FIG. 2B, a resist film 32 is formed on the semiconductor substrate 11 by photolithography method. The resist film 32 has an opening to expose the areas in which the NMOS transistors 12a, 13a are formed. Ions of P-type impurities such as boron (B) are implanted into the semiconductor substrate 11 using the resist film 32 as a mask, so that a P-type well layer 33 and a channel formation area (not shown) are formed.

After the resist film 32 is removed, a resist film (not shown) having an opening to expose the areas to form the PMOS transistors 12b, 13b is formed on the semiconductor substrate 11 by photolithography method. The resist film has an opening to expose the areas in which the PMOS transistors 12b, 13b are formed. Ions of N-type impurities such as phosphorus (P) are implanted into the semiconductor substrate 11 using the resist film as a mask, so that a channel formation area (not shown) is formed in an N-type well layer (N-type semiconductor substrate 11).

The NMOS transistors 12a, 13a are formed in the P-type well layer 33 of the N-type semiconductor substrate 11. The PMOS transistors 12b, 13b are formed in the N-type well layer (the N-type semiconductor substrate 11).

As shown in FIG. 2C, a silicon oxide film as the gate insulating film 14 is formed on the semiconductor substrate 11 by thermal oxidation method, for example. A polysilicon film doped with an impurity as a gate electrode material film 34 is formed on the gate insulating film 14 by CVD method.

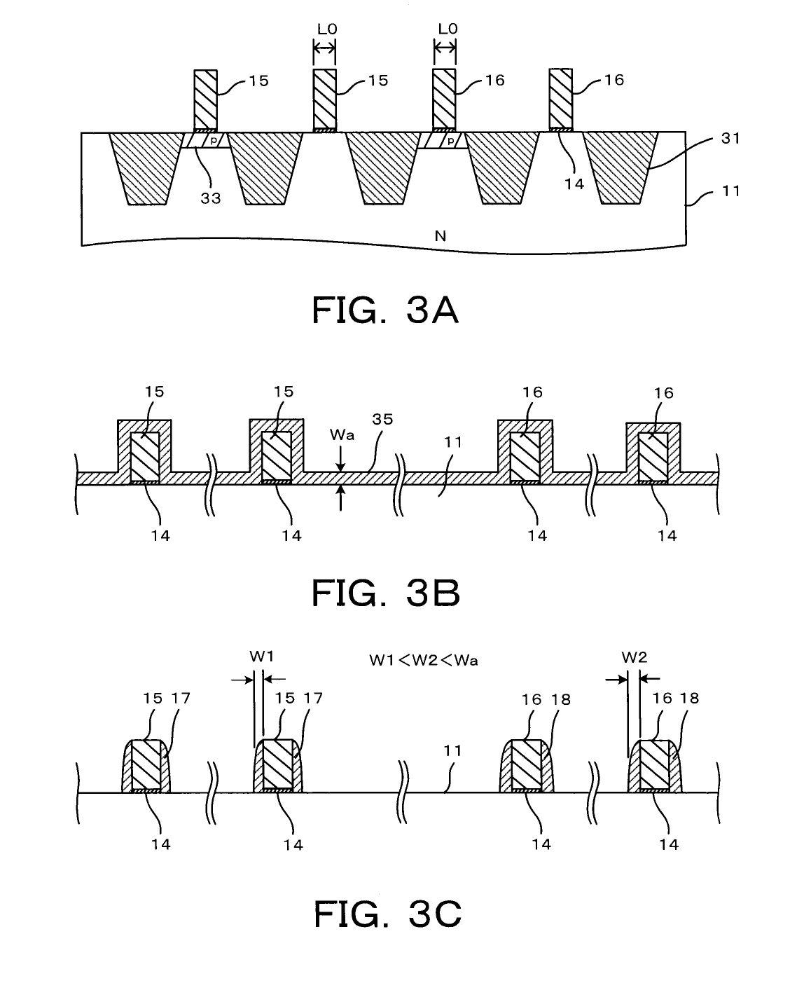

As shown in FIG. 3A, a mask material (not shown) is formed on the gate electrode material film 34 by photolithography method. The mask material includes a predetermined pattern which corresponds to the first gate electrode 15, the second gate electrode 16, the first gate dummy 25 and the second gate dummy 26. The gate electrode material film 34 is anisotropically etched by RIE method using the mask material.

Consequently, the first gate electrode 15, the second gate electrode 16, the first gate dummy 25 and the second gate dummy 26 are obtained.

As shown in FIG. 3B, a silicon oxide film with a thickness of Wa as a first insulating film 35 to cover the first and the second gate electrodes 15, 16 conformally is formed on the semiconductor substrate 11 by CVD method, for example. The thickness of Wa is set larger than the thickness of W1 and the thickness of W2 (i.e. W1<W2<Wa).

As shown in FIG. 3C, the first insulating film 35 is anisotropically etched by RIE method till the semiconductor substrate 11 is exposed. As described above, the etching rate of the first insulating film 35 is changed in accordance with the total coverage by loading effect. In the first region 11a having smaller total coverage, the etching rate of the first insulating film 35 becomes fast. In the second region 11b having larger total coverage, the etching rate of the first insulating film 35 becomes slow.

As a result, the first sidewall 17 with the thickness of W1 is formed in the first region 11a. The second sidewall 18 with the thickness of W2 larger than the thickness of W1 is formed in the second region 11b.

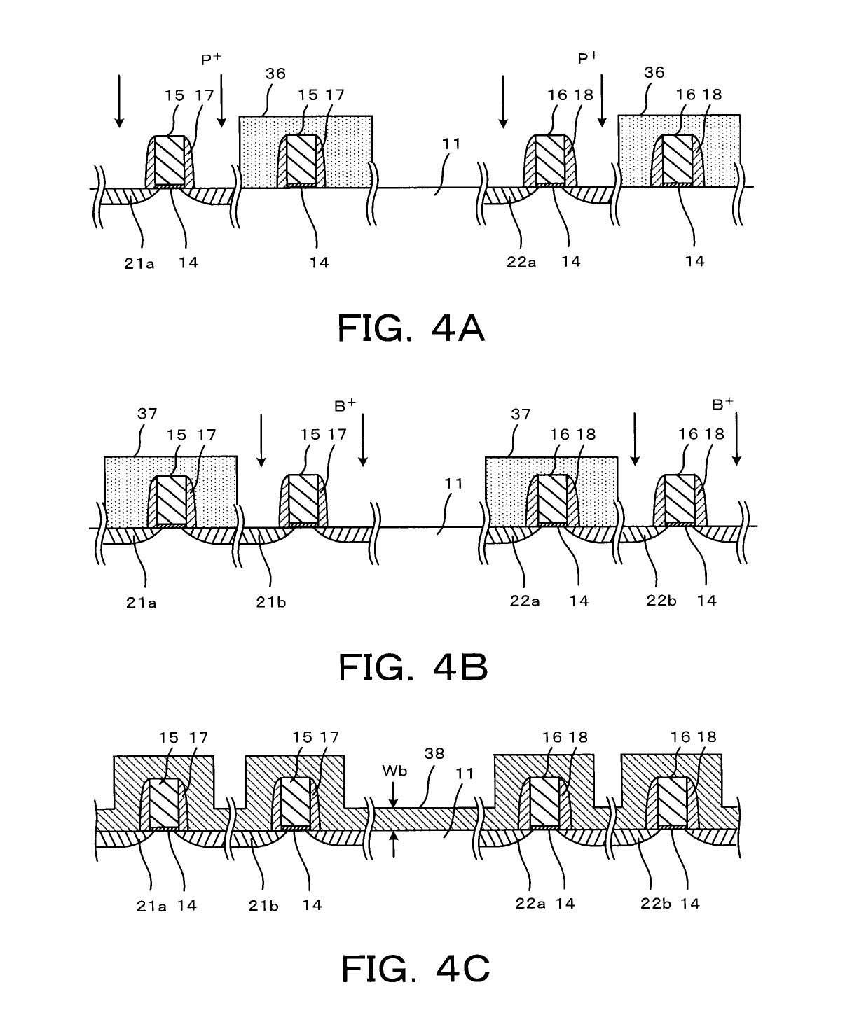

As shown in FIG. 4A, a resist film 36 is formed on the semiconductor substrate 11 by photolithography method. The resist film 36 has an opening to expose the areas in which the NMOS transistors 12a, 13a are formed.

Ions of N-type impurities such as phosphorus (P) are implanted into the P-type well layer 33 using both the first gate electrode 15 and the first side wall 17 as a mask in a self-align manner, so that the pair of first impurity diffusion layers 21a is formed so as to interpose the first gate electrode 15 in between.

Simultaneously, Ions of N-type impurities such as phosphorus (P) are implanted into the P-type well layer 33 using both the second gate electrode 16 and the second side wall 18 as a mask in a self-align manner, so that the pair of second impurity diffusion layers 22a is formed so as to interpose the second gate electrode 16 in between.

After the resist film 36 is removed, as shown in FIG. 4B, a resist film 37 is formed on the semiconductor substrate 11 by photolithography method. The resist film 37 has an opening to expose the areas in which the PMOS transistors 12b, 13b are formed.

Ions of P-type impurities such as boron (B) are implanted into the N-type well layer using both the first gate electrode 15 and the first side wall 17 as a mask in a self-align manner, so that the pair of second impurity diffusion layers 21b is formed so as to interpose the first gate electrode 15 in between.

Simultaneously, Ions of P-type impurities such as boron (B) are implanted into the N-type well layer using both the second gate electrode 16 and the second side wall 18 as a mask in a self-align manner, so that the pair of second impurity diffusion layers 22b is formed so as to interpose the second gate electrode 16 in between.

After the resist film 37 is removed, as shown in FIG. 4C, a silicon nitride film with a thickness of Wb as a second insulating film 38 to conformally cover the first gate electrodes 15 on which the first sidewall 17 is formed and the second gate electrode 16 on which the second sidewall 18 is formed is formed on the semiconductor substrate 11 by CVD method, for example. The thickness of Wb is set larger than the thickness of W3 and the thickness of W4 (i.e. W3<W4<Wb).

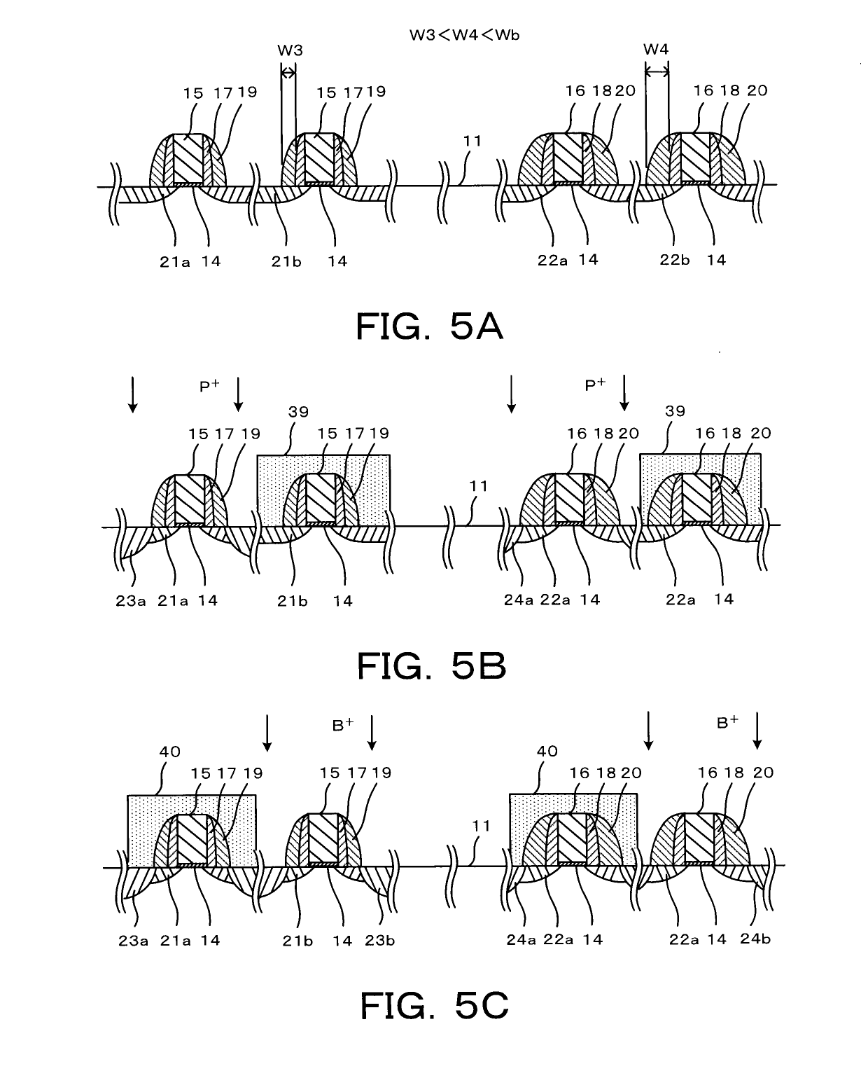

As shown in FIG. 5A, in a similar manner to FIG. 3C, the second insulating film 38 is anisotropically etched by RIE method till the semiconductor substrate 11 is exposed. In this time, as described above, the etching rate of the second insulating film 38 is changed in accordance with the total coverage by loading effect. In the first region 11a having smaller total coverage, the etching rate of the second insulating film 38 becomes fast. In the second region 11b having larger total coverage, the etching rate of the second insulating film 38 becomes slow.

As a result, the third sidewall 19 having the thickness of W3 is formed in the first region 11a. The fourth sidewall 20 having the thickness of W4 larger than the thickness of W3 is formed in the second region 11b.

As shown in FIG. 5B, in a similar manner to FIG. 4A, a resist film 39 is formed on the semiconductor substrate 11 by photolithography method. The resist film 39 has an opening to expose the areas in which the NMOS transistors 12a, 13a are formed. Ions of N-type impurities such as phosphorus (P) are implanted into the P-type well layer 33, so that the pair of third impurity diffusion layers 23a and the pair of the fourth impurity diffusion layers 24a are simultaneously formed.

As shown in FIG. 5C, in a similar manner to FIG. 4B, a resist film 40 is formed on the semiconductor substrate 11 by photolithography method. The resist film 40 has an opening to expose the areas in which the P MOS transistors 12b, 13b are formed. Ions of P-type impurities such as boron (B) are implanted into the N-type well layer, so that the pair of third impurity diffusion layers 23b and the pair of fourth impurity diffusion layers 24b are simultaneously formed.

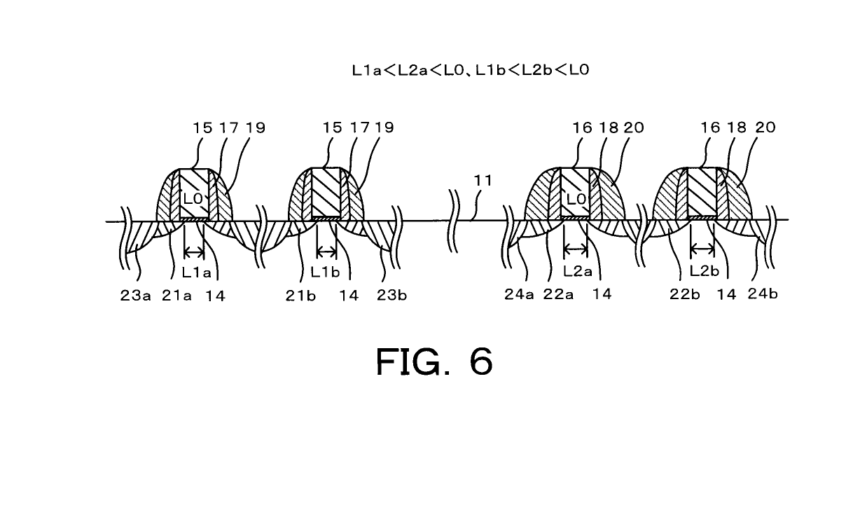

As shown in FIG. 6, the semiconductor substrate 11 is subjected to a heat treatment, so that Ions of phosphorus and Ions of boron which are implanted are electrically activated.

Ions of phosphorus diffuse within the P-type well layer 33 in vertical and horizontal directions, and extend up to the portion below the first gate electrode 15 beyond the first sidewall 17. The distance L1a between the pair of first impurity diffusion layers 21a is smaller than the width L0 of the first gate electrode 15.

Ions of phosphorus diffuse within the P-type well layer 33 in vertical and horizontal directions, and extend up to the portion below the second gate electrode 16 beyond the second sidewall 18. The distance L2a between the pair of second impurity diffusion layers 22a is smaller than the width L0 of the second gate electrode 16.

Similarly, Ions of boron diffuse within the N-type well layer in vertical and horizontal directions, and extend up to the portion below the first gate electrode 15 beyond the first sidewall 17. The distance L1b between the pair of first impurity diffusion layers 21b is smaller than the width L0 of the first gate electrode 15.

Ions of boron diffuse within the N-type well layer in vertical and horizontal directions, and extend up to the portion below the second gate electrode 16 beyond the second sidewall 18. The distance L2b between the pair of second impurity diffusion layers 22b is smaller than the width L0 of the second gate electrode 16.

Since the first thickness W1 of the first sidewall 17 is smaller than the second thickness W2 of the second sidewall 18, the distance L1a is shorter than the distance L2a (i.e. L1a<L2a). Similarly, the distance Lib is shorter than the distance L2b (i.e. L1b<L2b).

As a result, the threshold Vth1a of the NMOS transistor 12a is lower than the threshold Vth2a of the NMOS transistor 13a (i.e. Vth1a<Vth2a).

The threshold Vth1b of the PMOS transistor 12b is lower than the threshold Vth2b of the PMOS transistor 13b (i.e. Vth1b<Vth2b).

In addition, since the third thickness W3 of the third sidewall 19 is smaller than the fourth thickness W4 of the fourth sidewall 20, the distance between the pair of impurity diffusion layers 23a is smaller than the distance between the pair of impurity diffusion layers 24a. But, the threshold Vth1a and the threshold Vth2a are not affected at all.

Similarly, the distance between the pair of impurity diffusion layers 23b is smaller than the distance between the pair of impurity diffusion layers 24b. But, the threshold Vth1b and the threshold Vth2b are not affected at all.

A gate wiring (not shown) which is connected to the first and the second gate electrodes 15, 16 is formed. A source-drain wiring (not shown) which is connected to the third impurity diffusion layers 23a, 23b and the fourth impurity diffusion layers 24a, 24b is formed. The interlayer dielectric film (not shown) to cover the gate wiring and the source-drain wiring is formed on the semiconductor substrate 11.

Consequently, the semiconductor device 10 having the NMOS transistors 12a, 13a of which thresholds are different and the PMOS transistors 12b, 13b of which thresholds are different is obtained.

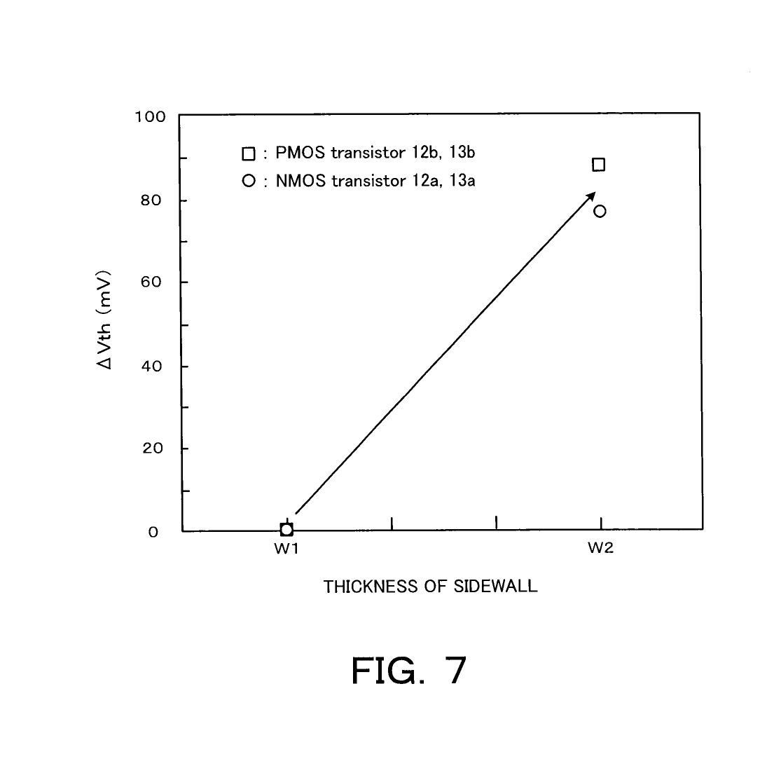

FIG. 7 is a graph showing the relation between the thickness of the sidewall and the threshold of the MOS transistor. In FIG. 7, a horizontal axis is the thickness W of the sidewall, and a vertical axis is the difference ΔVth between the threshold of the MOS transistor having the sidewall with the thickness W and the threshold of the MOS transistor having the sidewall with the thickness W1 (i.e. ΔVth=Vth(W)−Vth(W1)). An open circle denotes ΔVth of the NMOS transistor 12a, 13a. The open square denotes ΔVth of the PMOS transistor 12b, 13b.

As shown in FIG. 7, since the NMOS transistor 12a and the PMOS transistor 12b have the first sidewall 17 with the thickness W1, the difference ΔVth of the NMOS transistor 12a and the difference ΔVth of the PMOS transistor 12b are zero respectively in accordance with the definition, since the NMOS transistor 13a and the PMOS transistor 13b have the second sidewall 18 with the thickness W2 respectively, the difference ΔVth of the NMOS transistor 13a is 77 mV and the difference ΔVth of the PMOS transistor 13b is 88 mV.

Therefore, when the sidewalls of the NMOS transistor and the PMOS transistor become thick respectively, it is confirmed that the thresholds Vth of the NMOS transistor and the PMOS transistor become high respectively.

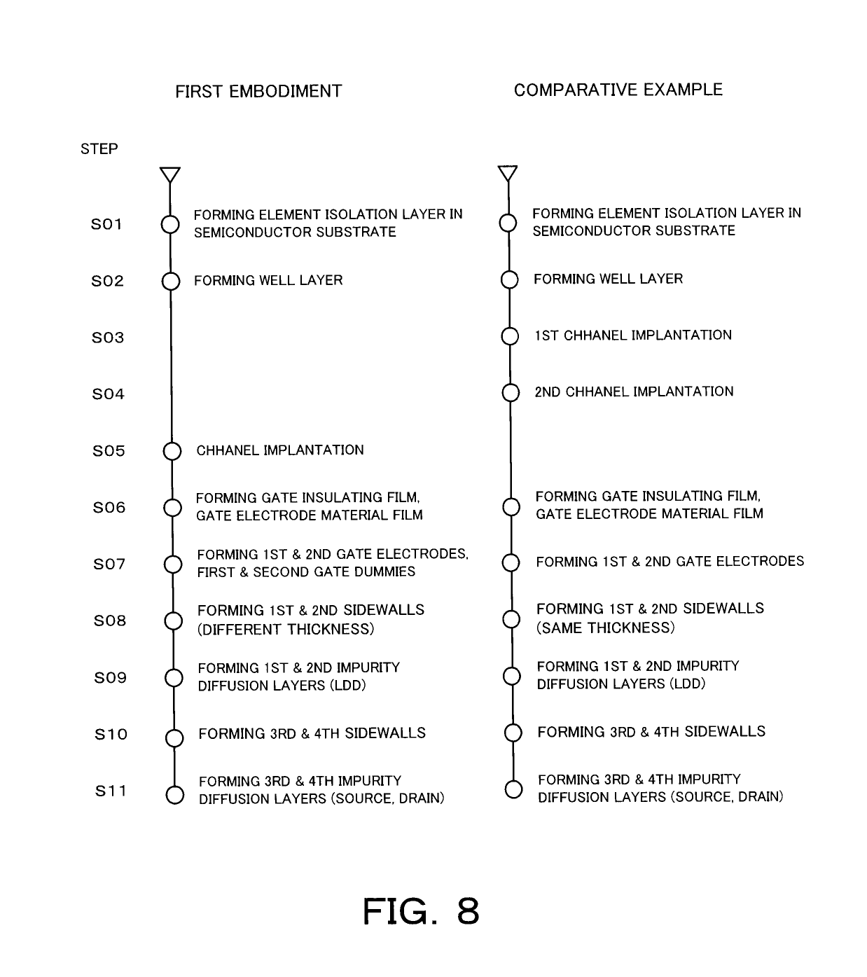

FIG. 8 is a flowchart showing steps of manufacturing the semiconductor device 10 of the embodiment in comparison with steps of manufacturing a semiconductor device of a comparative example. In FIG. 8, common steps between the steps of manufacturing the semiconductor device 10 of the embodiment and the steps of manufacturing the semiconductor device of the comparative example are denoted by the same reference numerals. The steps of manufacturing the semiconductor device of the comparative example are steps of manufacturing the semiconductor device in which ion implantations to form the channel are performed individually.

As shown in FIG. 8, the steps of manufacturing the semiconductor device 10 of the embodiment and the steps of manufacturing the semiconductor device of the comparative example contain the step of forming the element isolation layer in the semiconductor substrate (Step S01) and the step of forming the well layer in the semiconductor substrate (Step S02) respectively.

There is a difference in the step of forming the impurity diffusion layer for the channel. Specifically, in the steps of manufacturing the semiconductor device of the comparative example, a first channel implantation is performed into the first region after masking the second region, so that the impurity diffusion layer for the channel is formed in the first region (Step S03).

A second channel implantation is performed into the second region after masking the first region, so that the impurity diffusion layer for the channel is formed in the second region (Step S04). The dose amount of the first channel implantation and the dose amount of the second channel implantation are set to different value.

On the other hand, in the steps of manufacturing the semiconductor device 10, the channel implantation is simultaneously performed into the first and the second regions 11a, 11b at the same dose amount, so that the impurity diffusion layers for the channel are formed in the first and the second regions at once (Step S05).

Consequently, in the steps of manufacturing the semiconductor device of the comparative example, the channel implantation is required twice. On the contrary, in the steps of manufacturing the semiconductor device 10, the channel implantation is required only once.

The steps of manufacturing the semiconductor device 10 and the steps of manufacturing the semiconductor device of the comparative example contain Steps 06 to 11 respectively. Steps 06 to 11 are as follows: forming the gate electrode material film in the semiconductor substrate with the gate insulating film interposed in between (Step 06); forming the first gate electrode and the second gate electrode (Step 07); forming the sidewall on the first and the second gate electrodes (Step 08); forming the impurity diffusion layer for LDD (Lightly Doped Drain) (Step 09); forming the third sidewall and the fourth sidewall (Step 10); and forming the impurity diffusion layer for source-drain (Step 11).

There is a difference in Step 07. In Step 07 of the comparative example, only the first gate electrode and the second gate electrode are formed. On the contrary, in Step 07 of the embodiment, the first gate electrode, the second gate electrode, the first gate dummy and the second gate dummy are formed simultaneously.

Any special work is not needed in order to form the first and the second dummy gates, so that the number of steps is not increased. It is sufficient to beforehand prepare a photo mask having both a pattern which corresponds to the first and the second gate electrodes 15, 16, and a pattern which corresponds to the first and the second dummy gates 25, 26.

The performance results of Steps 08 and 09 are different with existence of the first and the second dummy gates 25, 26.

In Step 08 of the comparative example, the first sidewall and the second sidewall which have same thickness are formed. On the contrary, in Step 08 of the embodiment, the first sidewall 17 and the second sidewall 18 which have different thickness are formed by the influence of the first gate dummy 25 and the second gate dummy 26.

In Step 09 of the comparative example, the first impurity diffusion layer and the second diffusion layer which are same are formed. Specifically, the distance between the pair of first impurity diffusion layers become same as the distance between the pair of second impurity diffusion layers.

On the contrary, in Step 09 of the embodiment, the first impurity diffusion layer and the second diffusion layer which are different are formed. Specifically, the distance L1a between the pair of first impurity diffusion layers 21a becomes different from the distance L2a between the pair of second impurity diffusion layers 22a. The distance L1b between the pair of first impurity diffusion layers 21b becomes different from the distance L2b between the pair of second impurity diffusion layers 22b.

Specifically, in the manufacturing steps of the comparative example, the impurity concentrations of the channels are different so as to form the MOS transistors of which the thresholds are different. On the contrary, in the manufacturing steps of the embodiment, the impurity concentrations of the channels are same, but the structures of LDD are different so as to form the MOS transistors of which the thresholds are different.

As described above, in the manufacturing steps of the embodiment, the first gate dummy 25 having the first coverage is formed on the space area of the first region 11a and the second gate dummy 26 having the second coverage is formed on the space area of the second region 11b.

Since the total coverage of the second region 11b is set larger than the total coverage of the first region 11a, the first sidewall 17 with the first thickness W1 is formed on the first gate electrode 15 and the second sidewall 18 with the second thickness W2 is formed on the second gate electrode 16 simultaneously. Thereafter, the ion implantation to form the structure of LDD is performed.

As a result, the NMOS transistor 12a having the threshold Vth1a is formed in accordance with the first thickness W1. The NMOS transistor 13a having the threshold Vth2a higher than the threshold Vth1a is formed in accordance with the second thickness W2.

The PMOS transistor 12b having the threshold Vth1b is formed in accordance with the first thickness W1. The PMOS transistor 13b having the threshold Vth2b higher than the threshold Vth1b is formed in accordance with the second thickness W2.

Consequently, the manufacturing method of the semiconductor device including the MOS transistors of which thresholds are different is obtained.

In the MOS transistors of which thresholds are different, since the channel implantations are performed simultaneously, only one step of ion implantation is required. Further, since a random fluctuation of dose amount is prevented in advance, the difference of the thresholds can be stabilized.

By applying to steps of manufacturing SRAM (Static Random Access Memory), for example, the voltage margin of SRAM may be increased and reliability such as NBTI (Negative Bias Temperature Instability) may be improved. NBTI is a phenomenon in which the threshold of the MOS transistor changes under the influence of applied voltage or temperature over time.

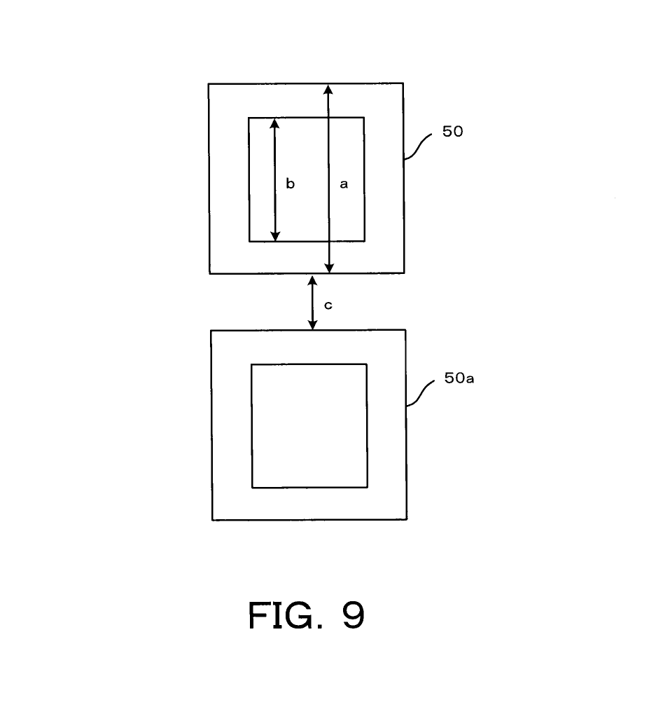

FIG. 9 is a plan view showing another gate dummy. As shown in FIG. 9, a gate dummy 50 is a square having an opening, what is called a picture frame. The coverage of the gate dummy 50 is expressed by a relationship of (a²−b²)/(a+c)², where “a” is the outer size of the square having the opening, “b” is the inner size and “c” is the distance from a square 50a adjacent.

In the gate dummy 50, the coverage changes in accordance with the inner size b. When the outer size a is set constant and the inner size b is varied, it is easy to adjust the coverage, for example.

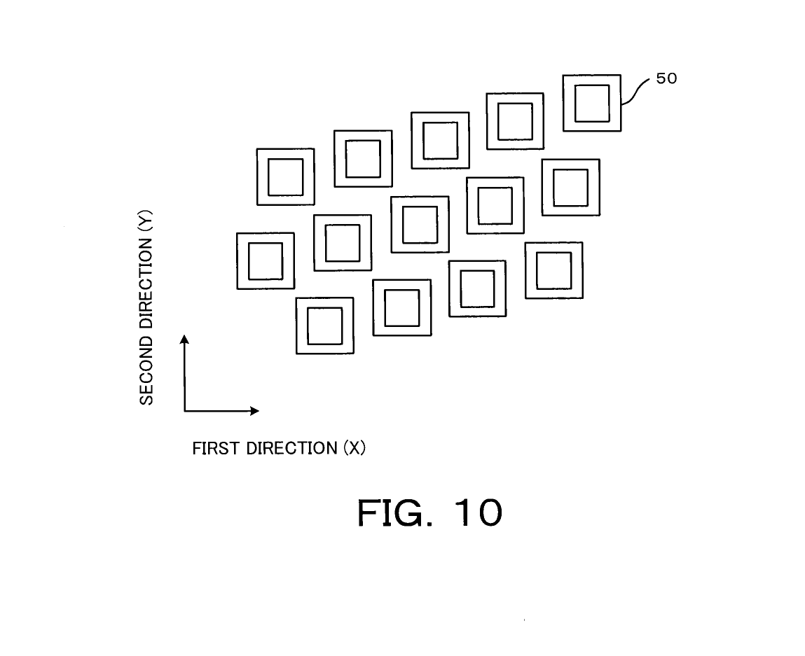

FIG. 10 is a plan view showing the multiple dummy gates 50 disposed in a dispersive manner, for example. As shown in FIG. 10, the dummy gates 50 are disposed in such a manner that the gate dummy 50 is moved in the order at predetermined pitches toward a first direction (X) and a second direction (Y) perpendicular to the X direction. The X direction is a direction parallel to the gate length of the gate electrode and the Y direction is a direction parallel to the gate width of the gate electrode.

Various patterns are available as the pattern which disposes two or more dummy gates 50 in a dispersive manner. The Various patterns are a right lattice, a hound's-tooth check, or a checkered pattern, for example.

The description has been given for the case where the first and the second dummy gates 25, 26 are the square. However, the first and the second dummy gates 25, 26 are not particularly limited to the above case and another shape such as a circle, a ring, for example, can be similarly available. The coverage is expressed by a relationship of 0.25*π(a²−b²)/(a+c)², where “a” is the outer diameter of the ring, “b” is the inner diameter of the ring and “c” is the distance from a ring adjacent. When the gate dummy is the circle, the inner diameter b is equal to 0.

Dummy gates of various shapes can be contained in the first and the second dummy gates 25, 26. The gate dummy of square and the gate dummy of the square having an opening can be mixed, for example.

The description has been given for the case where the semiconductor device 10 is a semiconductor device including the CMOS inverters of which the thresholds are different. However, the semiconductor device 10 can be a semiconductor device including NMOS transistors of which thresholds are different or PMOS transistors of which thresholds are different.

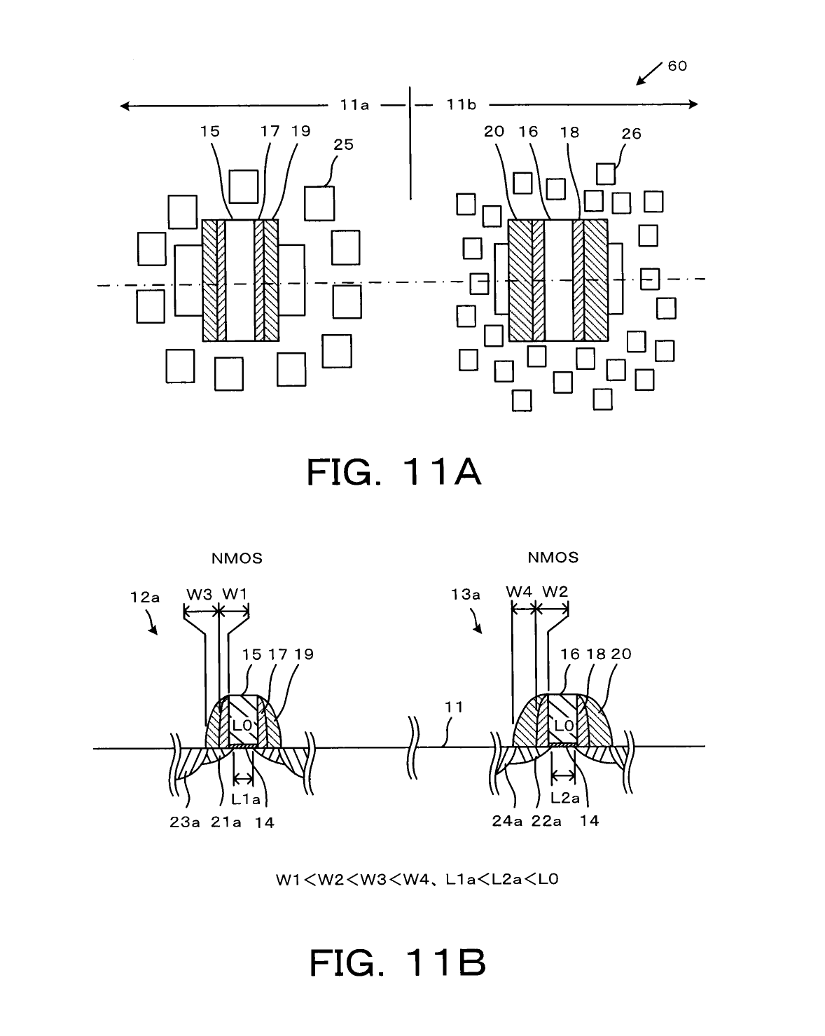

FIGS. 11A and 11B are views showing a semiconductor device having NMOS transistors of which thresholds are different. As shown in FIGS. 11A and 11B, a semiconductor device 60 has the NMOS transistor 12a and the NMOS transistor 12b. The threshold of the NMOS transistor 12b is higher than that of the NMOS transistor 12a.

In the steps of manufacturing the semiconductor device 60, the steps shown in FIG. 4B and FIG. 5C are not required. When the semiconductor substrate 11 is a P-type silicon substrate, the step shown in FIG. 2B is not required. It is also the same as described above when the MOS transistors of which thresholds are different are the PMOS transistors.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming a gate electrode material film on first and second regions of a semiconductor substrate having a first conductivity type with a gate insulating film interposed in between;
etching the gate electrode material film using a mask having a predetermined pattern anisotropically so as to form a first gate electrode and a plurality of first dummy gates on the first region and a second gate electrode and a plurality of second dummy gates on the second region, the first dummy gates having a first coverage respectively and being disposed so as to surround the first gate electrode, the second dummy gates having a second coverage different from the first coverage respectively and being disposed so as to surround the second gate electrode;
forming a first insulating film on the first and the second gate electrodes, and etching the first insulating film anisotropically so as to form a first sidewall on the first gate electrode and a second sidewall on the second gate electrode, the first sidewall having a first thickness, the second sidewall having a second thickness larger than the first thickness; and
implanting an impurity into the first and the second regions in a self-align manner so as to form a pair of first impurity diffusion layers and a pair of second impurity diffusion layers, the impurity having a second conductivity type, the first impurity diffusion layers being disposed so as to interpose the first gate electrode therebetween, the second impurity diffusion layers being disposed so as to interpose the second gate electrode therebetween.

2. The method of manufacturing the semiconductor device according to claim 1, wherein the first coverage is smaller than the second coverage.

3. The method of manufacturing the semiconductor device according to claim 1, further comprising:
implanting an impurity into the first and the second regions of the semiconductor substrate before forming the gate electrode material film, the impurity having the first conductivity type as the first and the second regions.

4. The method of manufacturing the semiconductor device according to claim 1, further comprising:
forming a second insulating film on both the first gate electrode having the first side wall and the second gate electrode having the second side wall, and etching the second insulating film anisotropically so as to form a third sidewall on the first gate electrode with the first side wall interposed in between and a fourth sidewall on the second gate electrode with the second sidewall interposed in between, the third sidewall having a third thickness, the fourth sidewall having a fourth thickness larger than the third thickness; and
implanting an impurity into the first and the second regions in a self-align manner so as to form a pair of third impurity diffusion layers and a pair of fourth impurity diffusion layers, the impurity having the second conductivity type to the first and the second regions, the third impurity diffusion layers being in contact with the first impurity diffusion layers, the fourth impurity diffusion layers being in contact with the second impurity diffusion layers.

5. The method of manufacturing the semiconductor device according to claim 1, wherein the first dummy gates and the second dummy gates are disposed in a dispersive manner.

6. The method of manufacturing the semiconductor device according to claim 5, wherein the first dummy gates and the second dummy gates are disposed in such a manner to advance in the order at predetermined pitches toward a first direction and a second direction perpendicular to the first direction.

7. The method of manufacturing the semiconductor device according to claim 1, wherein each first gate dummy and each second gate dummy are a square or a square having an opening, the first coverage and the second coverage are expressed by a relationship of (a²−b²)/(a+c)², where “a” is the size of the square, “b” is the size of the opening and “c” is the distance from a square adjacent.

8. The method of manufacturing the semiconductor device according to claim 1, wherein each first gate dummy and each second gate dummy are a circle or a circle having an opening, the first coverage and the second coverage are expressed by a relationship of (0.25π(a²−b²))/(a+c)², where “a” is the diameter of the circle, “b” is the diameter of the opening and “c” is the distance from a circle adjacent.

9. The method of manufacturing the semiconductor device according to claim 1, wherein the first thickness is determined in accordance with the product of the first coverage and the number of first dummy gates, the second thickness is determined in accordance with the product of the second coverage and the number of second dummy gates.

10. The method of manufacturing the semiconductor device according to claim 4, wherein the third thickness is determined in accordance with the product of the first coverage and the number of first dummy gates, the fourth thickness is determined in accordance with the product of the second coverage and the number of second dummy gates.

11. A method of manufacturing a semiconductor device, comprising:
implanting an impurity into first and second regions of the semiconductor substrate having a first conductivity type, the impurity having the first conductivity type;
forming a gate electrode material film on the first and the second regions of the semiconductor substrate with a gate insulating film interposed in between;
etching the gate electrode material film using a mask having a predetermined pattern anisotropically so as to form a first gate electrode and a plurality of first dummy gates on the first region and a second gate electrode and a plurality of second dummy gates on the second region, the first dummy gates having a first coverage respectively and being disposed so as to surround the first gate electrode, the second dummy gates having a second coverage different from the first coverage respectively and being disposed so as to surround the second gate electrode;
forming a first insulating film on the first and the second gate electrodes, and etching the first insulating film anisotropically so as to form a first sidewall on the first gate electrode and a second sidewall on the second gate electrode, the first sidewall having a first thickness, the second sidewall having a second thickness larger than the first thickness;
implanting an impurity into the first and the second regions in a self-align manner so as to form a pair of first impurity diffusion layers and a pair of second impurity diffusion layers, the impurity having an opposite conductivity type to the first and the second regions, the first impurity diffusion layers being disposed so as to interpose the first gate electrode therebetween, the second impurity diffusion layers being disposed so as to interpose the second gate electrode therebetween;
forming a second insulating film on both the first gate electrode having the first side wall and the second gate electrode having the second side wall, and etching the second insulating film anisotropically so as to form a third sidewall on the first gate electrode with the first side wall interposed in between and a fourth sidewall on the second gate electrode with the second sidewall interposed in between, the third sidewall having a third thickness, the fourth sidewall having a fourth thickness larger than the third thickness; and
implanting an impurity into the first and the second regions in a self-align manner so as to form a pair of third impurity diffusion layers and a pair of fourth impurity diffusion layers, the impurity having an opposite conductivity type to the first and the second regions, the third impurity diffusion layers being in contact with the first impurity diffusion layers, the fourth impurity diffusion layers being in contact with the second impurity diffusion layers.

12. The method of manufacturing the semiconductor device according to claim 11, wherein the first coverage is smaller than the second coverage.

13. The method of manufacturing the semiconductor device according to claim 11, wherein the first dummy gates and the second dummy gates are disposed in a dispersive manner.

14. The method of manufacturing the semiconductor device according to claim 13, wherein the first dummy gates and the second dummy gates are disposed in such a manner to advance in the order at predetermined pitches toward a first direction and a second direction perpendicular to the first direction.

15. The method of manufacturing the semiconductor device according to claim 11, wherein each first gate dummy and each second gate dummy are a square or a square having an opening, the first coverage and the second coverage are expressed by a relationship of (a²−b²)/(a+c)², where “a” is the size of the square, “b” is the size of the opening and “c” is the distance from a square adjacent.

16. The method of manufacturing the semiconductor device according to claim 11, wherein each first gate dummy and each second gate dummy are a circle or a circle having an opening, the first coverage and the second coverage are expressed by a relationship of (0.25π(a²−b²))/(a+c)², where “a” is the diameter of the circle, “b” is the diameter of the opening and “c” is the distance from a circle adjacent.

17. The method of manufacturing the semiconductor device according to claim 11, wherein the first thickness is determined in accordance with the product of the first coverage and the number of first dummy gates, the second thickness is determined in accordance with the product of the second coverage and the number of second dummy gates.

18. The method of manufacturing the semiconductor device according to claim 11, wherein the third thickness is determined in accordance with the product of the first coverage and the number of first dummy gates, the fourth thickness is determined in accordance with the product of the second coverage and the number of second dummy gates.
